(19) United States
(12) Patent Application Publication
(10) Pub. No.: US 2015/0255759 A1
(43) Pub. Date: Sep. 10, 2015

(54) HYBRID BARRIER STACKS AND METHODS OF MAKING THE SAME

(71) Applicant: SAMSUNG SDI CO., LTD., Yongin-si (KR)

(72) Inventors: Xianghui Zeng, Albany, CA (US); Lorenza Moro, Palo Alto, CA (US); Damien Boesch, San Jose, CA (US)

(21) Appl. No.: 14/637,296

(22) Filed: Mar. 3, 2015

Related U.S. Application Data
(60) Provisional application No. 61/950,800, filed on Mar. 10, 2014.

(51) Int. Cl. H01L 51/56; H01L 51/52

(52) U.S. Cl. CPC H01L 51/56; H01L 51/5256

(57) ABSTRACT

Barrier stacks according to embodiments of the present invention achieve good water vapor transmission rates with a reduced number of dyads (i.e., polymer layer/barrier layer couple). In some embodiments, the barrier stack includes one or more dyads comprising a first polymer decoupling layer and a hybrid barrier layer on the first layer. The hybrid barrier layer includes an inner oxide barrier layer and an outer silicon nitride barrier layer. The inner oxide barrier layer is deposited between the first layer and the outer silicon nitride layer of at least one of the dyads. The outer silicon nitride barrier layer is deposited by an evaporative deposition technique such as chemical vapor deposition (CVD), for example plasma enhanced chemical vapor deposition (PECVD). The barrier stack including the inner oxide barrier layer has a water vapor transmission rate that is lower than a water vapor transmission rate of a barrier stack not including the inner oxide barrier layer.

### CROSS-REFERENCE TO RELATED APPLICATION(S)

This application claims priority to, and the benefit of U.S. Provisional Application Ser. No. 61/950,800, filed on Mar. 10, 2014 and titled A METHOD TO MAKE HYBRID BARRIERS WITH GOOD ADHESION AND PERFORMANCE, the entire content of which is incorporated herein by reference.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are typically coated with a barrier coating or are encapsulated by incorporating a barrier stack adjacent one or both sides of the device.

Barrier coatings typically include a single layer of inorganic material, such as aluminum, silicon or aluminum oxides, or silicon nitrides. However, for many devices, a single layer barrier coating does not sufficiently reduce or prevent oxygen or water vapor permeability.

Indeed, in organic light emitting devices, for example, which require exceedingly low oxygen and water vapor transmission rates, single layer barrier coatings do not adequately reduce or prevent the permeability of damaging gases, liquids and chemicals. Accordingly, in those devices (e.g., organic light emitting devices and the like), barrier stacks have been used in an effort to further reduce or prevent the permeation of damaging gases, liquids and chemicals.

In general, a barrier stack includes multiple dyads, each dyad being a two-layered structure including a barrier layer and a decoupling layer. The barrier stack can be deposited directly on the device to be protected, or may be deposited on a separate film or support, and then laminated onto the device. The decoupling layer(s) and barrier layer(s) can be deposited by any of various techniques (e.g., vacuum deposition processes or atmospheric processes), but the deposition of suitably dense layers with appropriate barrier properties is typically achieved by supplying energy to the material that will ultimately form the layer. The energy supplied to the material can be thermal energy, but in many deposition processes, ionization radiation is used to increase the ion production in the plasma and/or to increase the number of ions in the evaporated material streams. The produced ions are then accelerated toward the substrate either by applying a DC or AC bias to the substrate, or by building up a potential difference between the plasma and the substrate.

For example, low energy plasma can be used to deposit the oxides of a barrier layer. However, a layer deposited using such low energy plasma has surface defects and low density, providing limited protection of the encapsulated device (e.g., an organic light emitting device) from the permeation of damaging gases, liquids, and chemicals. A common solution to these problems has been to provide multiple dyads (i.e., multiple stacks of the decoupling and barrier layers) in order to provide an effective barrier stack (or ultrabarrier). However, such a practice increases the cost and time of manufacture.

On the other hand, while higher energy plasma can be used to make higher quality barrier films, such high energy plasma can damage the underlying polymer decoupling layer. Additionally, some substrates (e.g., certain plastic substrates) cannot withstand the high energy and/or high temperatures of such a deposition process. As an alternative to these sputtering techniques, some barrier materials can be deposited by other, less damaging processes. For example, certain materials may be deposited by chemical vapor deposition techniques, which require lower temperatures, thereby reducing damage to the underlying polymer decoupling layer and/or substrate. However, these processes typically do not create barrier layers with sufficient barrier properties (e.g., water vapor and oxygen transmission rates) to effectively protect the underlying device. Accordingly, barrier layers deposited by these processes also require multiple dyads in order to provide an effective barrier stack (or ultrabarrier). However, as noted above, such a practice increases the cost and time of manufacture.

### SUMMARY

According to embodiments of the present invention, a barrier stack includes one or more dyads, where each dyad includes a first layer including a polymer or organic material, and a second barrier layer. The second barrier layer of the barrier stack includes an outer silicon nitride barrier layer, and an inner oxide barrier layer. The barrier stack including the inner oxide barrier layer may have a water vapor transmission rate that is lower than a water vapor transmission rate of a barrier stack including the outer silicon nitride barrier layer but not including the inner oxide barrier layer. Additionally, the barrier stack including the outer silicon nitride barrier layer may have a water vapor transmission rate that is lower than a water vapor transmission rate of a barrier stack including the inner oxide barrier layer but not including the outer silicon nitride barrier layer.

In some embodiments, the barrier stack may further include a fourth layer, where the first layer is on the fourth layer.

In some embodiments, the polymer or organic material is selected from organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

In some embodiments, the silicon nitride barrier layer comprises Si₃N₄.

In some embodiments, the inorganic oxide barrier layer includes an oxide of Al, Zr, Ti, Si, and combinations thereof. For example, the inorganic oxide barrier layer may include Al₂O₃ and/or SiO₂.

In some embodiments, the inner oxide barrier layer has a thickness of 20 nm or greater, for example 25 nm or greater. In some embodiments, for example, the inner oxide barrier layer has a thickness of 20 nm to 150 nm, for example 25 nm to 100 nm. In some embodiments for example, the inner oxide barrier layer has a thickness of 20 nm to 60 nm, or 25 nm to 60nm, for example 25 nm to 40 nm.

According to some embodiments, a method of making a barrier stack includes forming one or more dyads, where forming each of the dyads comprises forming a first layer comprising a polymer or organic material, and forming a hybrid barrier layer comprising an outer silicon nitride barrier layer and an inner oxide barrier layer. The barrier stack including the inner oxide barrier layer may have a water vapor transmission rate that is lower than a water vapor transmission rate of a barrier stack including the outer silicon nitride barrier layer but not including the inner oxide barrier layer. Additionally, the barrier stack including the outer silicon nitride barrier layer may have a water vapor transmission rate that is lower than a water vapor transmission rate of a barrier stack including the inner oxide barrier layer but not including the outer silicon nitride barrier layer.

The method may further include forming the first layer on a fourth layer.

In some embodiments, the inner oxide layer is deposited to a thickness of 20 nm or greater. For example, in some embodiments, the inner oxide layer is deposited to a thickness of 20 nm to 100 nm, or 25 nm to 100 nm.

In some embodiments, a barrier stack includes no more than 2 dyads, where each dyad includes a first layer including a polymer or organic material, and a second barrier layer including an outer silicon nitride barrier layer and an inner oxide barrier material. The barrier stack has a water vapor transmission rate on the order of 10⁻⁴ g/m²·day or better.

In some embodiments, the no more than 2 dyads includes no more than one dyad.

In some embodiments, the inner oxide barrier layer has a thickness of 20 nm or greater, for example 20 nm to 100 nm, or 25 nm to 100 nm.

### BRIEF DESCRIPTION OF THE DRAWINGS

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention; and

FIG. 3 is a schematic view of a barrier stack according to yet another embodiment of the present invention.

### DETAILED DESCRIPTION

In embodiments of the present invention, a barrier stack includes a hybrid barrier layer including a silicon nitride barrier layer and an inner oxide barrier layer on the decoupling layer of at least one dyad. The hybrid structure of the barrier layer of the barrier stack enables the reduction in the number of dyads needed to produce an “ultrabarrier” that is effective in protecting the underlying (or encapsulated) device from the permeation of moisture and oxygen, among other harmful elements. The inner oxide barrier layer is deposited between the decoupling layer of the dyad and the outer silicon nitride barrier layer, and promotes and improves adhesion of the silicon nitride barrier layer to the underlying polymer decoupling layer as well as improves the barrier performance of the hybrid barrier layer. The increased adhesion of the silicon nitride barrier layer to the underlying decoupling layer improves the barrier properties of the silicon nitride layer, and thereby contributes to the overall improvement in barrier properties of barrier stack including the hybrid barrier layer. Additionally, as sputtered inorganic oxides are good barriers themselves (and typically better barriers than silicon nitride layers), the inner oxide barrier layer also significantly contributes to the barrier performance of the barrier stack including the hybrid barrier layer structure. Indeed, in the hybrid barrier layer structure according to embodiments of the present invention, the inner oxide barrier layer and the outer silicon nitride layer work together to produce barrier properties that are better than either the inner oxide barrier layer or the outer silicon nitride barrier layer would produce alone. For example, the hybrid barrier layer including both an inner oxide barrier layer and an outer silicon nitride barrier layer has improved water vapor transmission properties compared to layers using only a silicon nitride layer or only an oxide layer, and fewer dyads are needed to provide target barrier properties (e.g., a target water vapor transmission rate).

In some embodiments of the present invention, a barrier stack includes at least one dyad, and each of the dyads includes a first layer that acts as a smoothing or planarization layer, and a second hybrid barrier layer that provides the barrier properties to the barrier stack. The hybrid barrier layer includes an inner oxide layer (including an inorganic oxide barrier material) and an outer silicon nitride barrier layer (including a silicon nitride barrier material). The layers of the barrier stack can be directly deposited on a device to be encapsulated (or protected) by the barrier stack, or may be deposited on a separate substrate or support, and then laminated on the device. As used herein, the terms “outer” and “inner” refer to the proximity of the identified layer to the substrate (or encapsulated device) or the first layer (decoupling layer). In particular, where a layer is described as an “inner” layer, that layer is closer to the substrate or first layer, and where a layer is described as an “outer” layer, that layer is closer to the substrate or first layer. Accordingly, as described herein, the inner oxide barrier layer is closer to the substrate or first layer than the outer silicon nitride barrier layer.

The first layer of the dyad includes a polymer or other organic material that serves as a planarization, decoupling and/or smoothing layer. Specifically, the first layer decreases surface roughness, and encapsulates surface defects, such as pits, scratches, digs and particles, thereby creating a planarized surface that is ideal for the subsequent deposition of additional layers. As used herein, the terms “first layer,” “smoothing layer,” “decoupling layer,” and “planarization layer” are used interchangeably, and all terms refer to the first layer, as now defined. The first layer can be deposited directly on the device to be encapsulated (e.g., an organic light emitting device), or may be deposited on a separate support. The first layer may be deposited on the device or substrate by any suitable deposition technique, some nonlimiting examples of which include vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The first layer can include any suitable material capable of acting as a planarization, decoupling and/or smoothing layer. Some nonlimiting examples of suitable such materials include organic polymers, inorganic polymers, organometallic polymers, hybrid organic/inorganic polymer systems, and silicates. In some embodiments, for example, the material of the first layer may be an acrylate-containing polymer, an alkylacrylate-containing polymer (including but not limited to methacrylate-containing polymers), or a silicon-based polymer.

The first layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the first layer. In some embodiments, for example, the first layer has a thickness of about 100 to 1000 nm.

The second hybrid barrier layer of the dyad is the layer that operates as the barrier layer, preventing the permeation of damaging gases, liquids and chemicals to the encapsulated device.

As used herein, the terms “second layer” and “hybrid barrier layer” are used interchangeably. The second layer includes an outer silicon nitride barrier layer that is deposited on the inner oxide layer by an evaporative deposition technique. For example, the silicon nitride of the outer silicon nitride layer may be deposited by chemical vapor deposition (CVD), e.g., plasma enhanced chemical vapor deposition (PECVD). The conditions of evaporative deposition (e.g., CVD or PECVD) are not particularly limited. In some embodiments, however, the deposition process includes the plasma enhanced chemical vapor deposition of the silicon nitride film using of silane (SiH₄) and ammonia (NH₃) source gases Indeed, the deposition of silicon nitride and similar materials using these deposition techniques is well known in the art, and those of ordinary skill in the art would be readily capable of selecting suitable conditions and deposition parameters to deposit a silicon nitride (or similar material) film with the thickness described in this application. However, some suitable PECVD sources include sources with a shower, which are mainly used for the static deposition of films on discrete substrate,s or linear sources (e.g., MicroWave antenna-like sources such as those available from Roth & Rau B.V. (Netherlands). Linear sources are well suited for deposition on webs. PECVD sources may operate with radio frequency (RF) or microwave (MW) power supplies and may include (or not include) biasing of the substrate. Films deposited on biased substrates are denser, and are therefore more effective barriers.

The silicon nitride material of the outer silicon nitride barrier layer is not particularly limited, and may be any silicon nitride suitable for substantially preventing or reducing the permeation of damaging gases, liquids and chemicals (e.g., oxygen and water vapor) to the encapsulated device. In some embodiments, however, the silicon nitride material (SiNₓ) may be Si₃N₄.

The thickness of the outer silicon nitride barrier layer is also not particularly limited. In some embodiments, for example, the thickness of the outer silicon nitride barrier layer is equal to or greater than the thickness of the inner oxide barrier layer. For example, in some embodiments, a ratio of the thickness of the inner oxide barrier layer to the thickness of outer silicon nitride barrier layer is 1:4 to 2:5, for example, 1:4 or 2:5. In some embodiments, the ratio of the thickness of the inner oxide barrier layer to the outer oxide barrier layer is 1:1. In some embodiments, the silicon nitride barrier layer may have a thickness of 20 nm to 150 nm, for example 20 nm to 100 nm, or 60 nm to 100 nm or 40 nm to 100 nm. In some embodiments, for example, the thickness of the outer silicon nitride barrier layer may be 100 nm.

According to embodiments of the present invention, the hybrid barrier layer of the barrier stack includes an inner oxide barrier layer that includes a metal oxide material, and serves as both an adhesion promoting layer for improving adhesion between the outer silicon nitride barrier layer and the decoupling layer (i.e., the first layer), and as a barrier layer, contributing significantly to the performance (i.e., the barrier properties, e.g., water vapor transmission rate) of the hybrid barrier layer as a barrier. To accomplish both of these goals, the inner oxide barrier layer is deposited between the first layer and the outer silicon nitride barrier layer to a thickness suitable for both promoting adhesion and contributing measurably to the barrier property of the barrier stack. As used herein, “contributing measurably” means that a barrier stack with both the outer silicon nitride barrier layer and the inner oxide barrier layer has a barrier property (e.g., water vapor transmission rate) that is measurably better than a barrier stack including only the outer silicon barrier layer (but not the inner oxide barrier layer). In some embodiments, for example, the inner oxide barrier layer has a thickness of 25 nm or greater (or in some embodiments, greater than 25 nm), for example 20 nm or greater (or in some embodiments, greater and 20 nm). For example, in some embodiments, the inner oxide barrier layer has a thickness of 20 nm to 150 nm, for example 25 nm to 150 nm. In some embodiments, for example, the inner oxide barrier layer has a thickness of 20 nm to 100 nm, for example 25 nm to 100 nm. For example, in some embodiments, the inner oxide barrier layer has a thickness of 20 nm to 60 nm, for example, 25nm to 60 nm. In some embodiments, the inner oxide barrier layer has a thickness of 20 nm to 40 nm, for example 25 nm to 40 nm. For example, in some embodiments, the inner oxide barrier layer has a thickness of 40 nm.

As discussed above, the inner oxide barrier layer is deposited on the first layer, and the outer silicon nitride barrier layer is deposited on the inner oxide barrier layer. Deposition of the inner oxide barrier layer may vary depending on the material used for the inner oxide barrier layer. However, in general, any deposition technique and any deposition conditions can be used to deposit the inner oxide barrier layer. For example, the inner oxide barrier layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof.

In some embodiments, however, the inner oxide barrier layer is deposited by AC or DC sputtering. For example, in some embodiments, the intervening tie layer is deposited by AC sputtering. The AC sputtering deposition technique offers the advantages of faster deposition, process stability, control, fewer particles and fewer arcs. The conditions of the AC sputtering deposition are not particularly limited, and as would be understood by those of ordinary skill in the art, the conditions will vary depending on the area of the target and the distance between the target and the substrate. In some exemplary embodiments, however, the AC sputtering conditions may include a power of about 3 to about 6 kW, for example about 4 kW, a pressure of about 2 to about 6 mTorr, for example about 4.4 mTorr, an Ar flow rate of about 80 to about 120 sccm, for example about 100 sccm, a target voltage of about 350 to about 550 V, for example about 480V, and a track speed of about 90 to about 200 cm.min, for example about 141 cm/min. Also, although the inert gas used in the AC sputtering process can be any suitable inert gas (such as helium, xenon, krypton, etc.), in some embodiments, the inert gas is argon (Ar).

The material of the inner oxide barrier layer is not particularly limited, and may be any inorganic oxide material suitable for both promoting adhesion of the outer silicon nitride barrier layer to the polymer decoupling layer (i.e., the first layer) and contributing measurably to a barrier property (e.g., water vapor transmission rate) of the barrier stack. Some nonlimiting examples of suitable materials for the inner oxide barrier layer include metal oxides, for example metal oxides of metals including Al, Zr, Si or Ti. In some embodiments, for example, the inner oxide barrier layer includes aluminum oxide or silicon oxide (e.g., Al₂O₃ or SiO₂).

In some embodiments, only one of the dyads of the barrier stack includes the hybrid barrier layer described herein, and the remaining dyads of the barrier stack include a single layer barrier layer including either an oxide barrier layer or a silicon nitride barrier layer (but not both). For example, in some embodiments, the inner oxide barrier layer may be deposited between the first layer and the outer silicon nitride barrier layer of only the outermost dyad (i.e., the dyad furthest from the substrate or encapsulated device). In some embodiments, for example, the inner oxide barrier layer may be deposited between the first layer and outer silicon nitride barrier layer of only the innermost dyad (i.e., the dyad closest to the substrate or encapsulated device). For example, in some embodiments, an inner oxide barrier layer may be deposited between the first layer and the outer silicon nitride barrier layer of both the innermost and outermost dyads. In some embodiments, an inner oxide barrier layer may be deposited between the first layer and the outer silicon nitride layer of each of the dyads in the barrier stack. In some embodiments, for example, the barrier stack includes only one dyad, and therefore only one inner oxide barrier layer between the first layer and the outer silicon nitride barrier layer of the only dyad. Indeed, as the inner oxide barrier layer both improves adhesion between the first layer and the outer silicon nitride barrier layer of the dyad, and contributes measurably to the barrier performance of the barrier stack, in some embodiments, the barrier stack includes a reduced number of dyads, e.g., 2 or fewer dyads, for example 1 dyad. Even though the barrier stacks according to such embodiments include fewer dyads, they achieve improved barrier properties, such as water vapor transmission rate.

In particular, in some embodiments, the barrier stack without the inner oxide barrier layer registers a water vapor transmission rate that is measurably greater than the water vapor transmission rate of the same barrier stack including the inner oxide barrier layer. For example, in some embodiments, the inclusion of the inner oxide barrier layer according to embodiments of the present invention can improve the water vapor transmission rate of the barrier stack by up to a full order of magnitude, and in some embodiments, by 1 to 3 full orders of magnitude, for example 2 to 3 full orders of magnitude, or 2 full orders of magnitude. Specifically, in some embodiments, the barrier stack without the inner oxide barrier layer may have a water vapor transmission rate on the order of 10⁻¹ g/m²·day to 10⁻³ g/m²·day, and the barrier stack with the inner oxide barrier layer may have a water vapor transmission rate of 10⁻⁴ g/m²·day to 10⁻⁵ g/m²·day.

In depositing the inner oxide barrier layer by sputtering, as discussed above, defects are introduced in the inner oxide barrier layer by the vacuum deposition process and the handling of the films. These defects are mainly created by particles falling on the substrate before and during the deposition process, as well as scratches and indentations created by handling (e.g., contact with rolls in web systems). The extrinsic defects created in the barrier layer during the production process are ingress paths for moisture and oxygen. These defects render the highly impermeable dense inner oxide barrier layer less effective (by itself) as a permeation barrier against moisture and oxygen. The standard approach to minimize the impact of these defects is the use of multilayer barrier structures including a stack of several dyads. One of the functions of the organic layer (i.e., the first layer in the dyad) in such structures is to cover the particles on the substrate and landing on it during barrier fabrication. Another function of the organic polymer layer (i.e., the first layer of the dyad) is to provide a smooth surface for the deposition of a high quality inorganic barrier layer (e.g., the inner oxide barrier layer of the dyad). However, deposition of multiple dyads (as is standard protocol to minimize the impact of defects) increases the cost of fabrication of the final devices. In addition, when the number of dyads increases, the benefit of additional layers progressively diminishes because the additional fabrication rounds lead to more added defects.

Accordingly, in some embodiments of the present invention, the outer silicon nitride barrier layer functions not only as its own barrier layer, but also as a defect-healing layer for the underlying inner oxide barrier layer. In particular, as the outer silicon nitride barrier layer is deposited by an evaporative deposition process, the resulting outer silicon nitride barrier layer also acts as conformal coating on the underlying inner oxide barrier layer, which seals the defects inherent in the inner oxide barrier layer from the vacuum deposition process and handling. As such, the outer silicon nitride barrier layer acts as both a barrier layer and a defect-healing layer for minimizing or mitigating the effects of defects in the underlying inner oxide barrier layer.

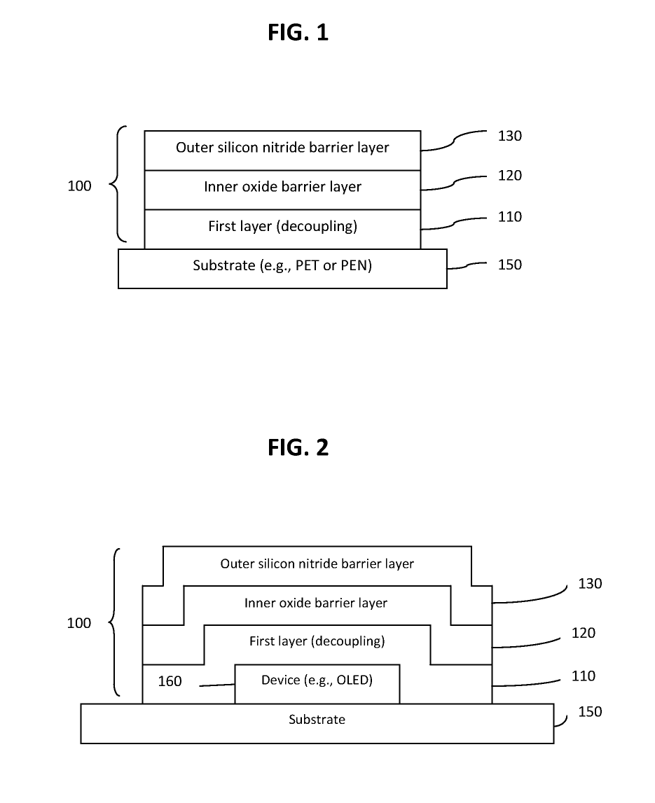

Exemplary embodiments of a barrier stack according to the present invention are illustrated in FIGS. 1 and 2. The barrier stack 100 depicted in FIG. 1 includes a first layer 110 which includes a decoupling layer or smoothing layer (i.e., the first layer discussed above), and a hybrid barrier layer including an inner oxide barrier layer 120, and an outer silicon nitride barrier layer 130. In FIG. 1, the barrier stack 100 is deposited on a substrate 150, for example glass or plastic (such as, for example, polyethylene naphthalate (PEN) or polyethylene terephthalate (PET)). However, in FIG. 2, the barrier stack 100 is deposited directly on the device 160, e.g., an organic light emitting device.

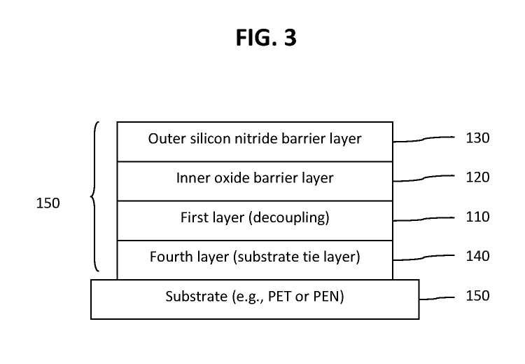

In addition to the first layer 110 and hybrid barrier layer (including the inner oxide barrier layer 120 and outer silicon nitride barrier layer 130) making up a dyad, some exemplary embodiments of the barrier stack 100 can include a fourth layer 140 between the first layer 110 and the substrate 150 or the device 160 to be encapsulated. Although the inventive barrier stacks are discussed herein and depicted in the accompanying drawings as including, for example, a “first” layer and a “fourth” layer 140, it is understood that the layers of the barrier stack may be deposited on the substrate 150 or the device 160 in any order so long as the inner oxide barrier layer 130 is between the first layer 110 and the outer silicon nitride barrier layer 130 of at least one of the dyads, and the identification of the first and fourth layers as “first” and “fourth,” respectively, does not mean that these layers must be deposited in that order. Indeed, as discussed here, and depicted in FIG. 3, in some embodiments, the fourth layer 140 is deposited on the substrate 150 or device 140 prior to deposition of the first layer 110.

The fourth layer 140 acts as a substrate tie layer, improving adhesion between the layers of the barrier stack 100 and the substrate 150 or the device 160 to be encapsulated. In particular, the fourth layer 140 is typically the first layer deposited on the substrate, prior to deposition of the first layer 110 (i.e., the polymer decoupling layer), and acts to improve adhesion of the first layer to the substrate or device for encapsulation. The material of the fourth layer 140 is not particularly limited, and can include the materials described above with respect to the inner oxide barrier layer 120. Also, the material of the fourth layer may be the same as or different from the material of the inner oxide barrier layer 120. The materials of the inner oxide barrier layer 120 are described in detail above.

Additionally, the fourth layer may be deposited on the substrate or the device to be encapsulated by any suitable technique, including, but not limited to the techniques described above with respect to the inner oxide barrier layer. In some embodiments, for example, the fourth layer may be deposited by AC or DC sputtering under conditions similar to those described above for the inner oxide barrier layer. Also, the thickness of the deposited fourth layer is not particularly limited, and can be any thickness suitable to effect good adhesion between the first layer of the barrier stack and the substrate or device to be encapsulated. In some embodiments, for example, the fourth (substrate tie) layer can have a thickness of about 20 nm to about 60 nm, for example, about 40 nm.

An exemplary embodiment of a barrier stack 100 according to the present invention including a fourth layer 140 is depicted in FIG. 3. The barrier stack 100 depicted in FIG. 3 includes a first layer 110 which includes a decoupling layer, a fourth layer 140 which includes a substrate tie layer, a hybrid barrier layer including an inner oxide barrier layer 120, and an outer silicon nitride barrier layer 130. In FIG. 3, the barrier stack 100 is deposited on a substrate 150, for example glass or plastic (e.g., PET or PEN). However, it is understood that the barrier stack 100 can alternatively be deposited directly on the device 160, e.g., an organic light emitting device, as depicted in FIG. 2 with respect to the embodiments excluding the fourth layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a first layer 110 on the substrate. The first layer 110 is as described above and acts as a decoupling/smoothing/planarization layer. As also discussed above, the first layer 110 may be deposited on the device 160 or substrate 150 by any suitable deposition technique, including, but not limited to, vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The method further includes depositing a hybrid barrier layer on the first layer 110, where depositing the hybrid barrier layer includes depositing an inner oxide barrier layer 120 and depositing an outer silicon nitride barrier layer 130. The inner oxide barrier layer 120 is deposited on the first layer 110. The inner oxide barrier layer 120 is as described above and acts as both an adhesion promoting layer (serving to promote or improve adhesion of the subsequently deposited outer silicon nitride barrier layer 130 to the first layer 110) and as a barrier layer (contributing measurably to a barrier property (e.g., water vapor transmission rate) of the barrier stack. The deposition of the inner oxide barrier layer 120 may vary depending on the material used for the inner oxide barrier layer. However, in general, any deposition technique and any deposition conditions can be used to deposit the inner oxide barrier layer. For example, the inner oxide barrier layer 120 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof. In some embodiments, however, the inner oxide barrier layer 120 is deposited by AC or DC sputtering, for example pulsed AC or pulsed DC sputtering. While any suitable conditions for deposition can be employed, some suitable conditions are described above.

As discussed above, the inner oxide barrier layer both improves adhesion between the first layer and the outer silicon nitride layer, and contributes measurably to the barrier performance of the barrier stack. The inner oxide barrier layer is deposited between the first layer and the outer silicon nitride barrier layer to a thickness suitable for accomplishing both goals (i.e., promoting adhesion, and contributing measurably to the barrier property of the barrier stack). In some embodiments, for example, the inner oxide barrier layer has a thickness of 25 nm or greater (or in some embodiments, greater than 25 nm), for example 20 nm or greater (or in some embodiments, greater and 20 nm). For example, in some embodiments, the inner oxide barrier layer has a thickness of 20 nm to 150 nm, for example 25 nm to 150 nm. In some embodiments, for example, the inner oxide barrier layer has a thickness of 20 nm to 100 nm, for example 25 nm to 100 nm. For example, in some embodiments, the inner oxide barrier layer has a thickness of 20 nm to 60 nm, for example, 25 nm to 60 nm. In some embodiments, the inner oxide barrier layer has a thickness of 20 nm to 40 nm, for example 25 nm to 40 nm. For example, in some embodiments, the inner oxide barrier layer has a thickness of 40 nm.

Additionally, deposition of the hybrid barrier layer further includes depositing an outer silicon nitride layer 130 on the inner oxide barrier layer 120. The outer silicon nitride barrier layer 130 is as described above and acts both as the barrier layer of the barrier stack (serving to substantially prevent or substantially reduce the permeation of damaging gases, liquids and chemicals to the underlying device) and as a defect-healing layer (serving to seal (or heal) defects in the underlying inner oxide barrier layer that are caused by the vacuum deposition process and handling). As discussed above, the outer silicon nitride barrier layer includes a silicon nitride that is deposited on the inner oxide barrier layer by an evaporative deposition technique. For example, the silicon nitride of the outer silicon nitride barrier layer may be deposited by chemical vapor deposition (CVD), e.g., plasma enhanced chemical vapor deposition (PECVD). As discussed above, the conditions of evaporative deposition (e.g., CVD or PECVD) are not particularly limited. In some embodiments, however, the deposition process includes the plasma enhanced chemical vapor deposition of the silicon nitride film using silane (SiH₄) and ammonia (NH₃) source gases Indeed, the deposition of silicon nitride and similar materials using these deposition techniques is well known in the art, and those of ordinary skill in the art would be readily capable of selecting suitable conditions and deposition parameters to deposit a silicon nitride (or similar material) film with the thickness described in this application.

According to some embodiments, the method may further include pretreating the inner oxide barrier layer with a suitable plasma or gas prior to depositing the outer silicon nitride barrier layer. The material of the pretreatment gas or plasma is not particularly limited. However, in some embodiments, the inner oxide barrier layer may be pretreated with O₂ or NH₃. Some additional nonlimiting examples of suitable gases and/or plasmas for pretreating the inner oxide barrier layer include Ar and N₂. The process of pretreating an underlying substrate prior to evaporative deposition of a silicon nitride is known in the art, and those of ordinary skill in the art would be capable of selecting suitable parameters for this pretreatment.

In some embodiments, the method further includes depositing a fourth layer 140 between the substrate 150 (or the device 160 to be encapsulated) and the first layer 110. The fourth layer 140 is as described above and acts as a substrate tie layer for improving adhesion between the substrate or device and the first layer 110 of the barrier stack 100. The fourth layer 140 may be deposited by any suitable technique, as discussed above. For example, as also discussed above, the fourth layer 140 may be deposited on the substrate 150 (or the device 160 to be encapsulated) by AC or DC sputtering, e.g., pulsed AC or pulsed DC sputtering.

As discussed above, according to embodiments of the present invention, a barrier stack includes at least one dyad including a first layer (i.e., a smoothing, planarization and/or decoupling layer), and a hybrid barrier layer including an inner oxide barrier layer and an outer silicon nitride barrier layer. The inner oxide barrier layer increases the reliability of the barrier created by the barrier stack, contributes measurably to the barrier performance of the stack, and enables a reduction in the number of dyads needed to create an effective barrier. For example, where other barrier stacks not including an inner oxide barrier layer may require 3 or more dyads to create a barrier with a sufficient water vapor transmission rate (e.g., a water vapor transmission rate on the order of 10⁻⁴ b/m²·day), barrier stacks including an inner oxide barrier layer according to embodiments of the present invention can achieve the same or better water vapor transmission rate (e.g., a water vapor transmission rate on the order of 10⁻⁴ b/m²·day or better, for example, 10⁻⁵ b/m²·day or better) with fewer than 3 dyads, for example 1 or 2 dyads. For example, in some embodiments, the barrier stack includes no more than 2 dyads. Indeed, in some embodiments, the barrier stack includes only one dyad.

Additionally, the barrier stacks according to embodiments of the present invention achieve improved barrier properties compared to similar barrier stacks not including the inner oxide barrier layer. For example, where similar single dyad silicon nitride barrier stacks not including an inner oxide barrier layer between the first layer and an outer silicon nitride barrier layer may achieve a water vapor transmission rate on the order of 10⁻² b/m²·day or at best 10⁻³ b/m²·day, the barrier stacks according to embodiments of the present invention can achieve improved water vapor transmission rates of 10⁻⁴ b/m²·day or better (for example, 10⁻⁵ b/m²·day or better) with a single dyad. The barrier stacks according to embodiments of the present invention can be used for either direct thin film encapsulation of sensitive devices (such as, e.g., OLEDs), or for ultra-barrier laminates deposited on a plastic foil to be used as a substrate or encapsulation by lamination of the sensitive device.

While certain exemplary embodiments of the present invention have been illustrated and described, it is understood by those of ordinary skill in the art that certain modifications and changes can be made to the described embodiments without departing from the spirit and scope of the present invention.

What is claimed is:

1. A barrier stack, comprising:
one or more dyads, each dyad comprising a first layer comprising a polymer or organic material, and an outer silicon nitride barrier layer; and
an inner oxide barrier layer between the first layer and the outer silicon nitride layer of one or more of the one or more dyads.

2. The barrier stack of claim 1, wherein the barrier stack including the inner oxide barrier layer has a water vapor transmission rate that is lower than a water vapor transmission rate of a barrier stack comprising the one or more dyads but not including the inner oxide barrier layer.

3. The barrier stack of claim 1, further comprising a fourth layer, wherein the first layer is on the fourth layer.

4. The barrier stack of claim 1, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

5. The barrier stack of claim 1, wherein the outer silicon nitride barrier layer comprises Si₃N₄.

6. The barrier stack of claim 1, wherein the inner oxide barrier layer comprises an oxide of Al, Zr, Ti, Si, and combinations thereof.

7. The barrier stack of claim 1, wherein the inner oxide barrier layer comprises Al₂O₃ and/or SiO₂.

8. The barrier stack of claim 1, wherein the inner oxide barrier layer has a thickness of 20 nm or greater.

9. The barrier stack of claim 1, wherein the inner oxide barrier layer has a thickness of 20 nm to 100 nm.

10. A method of making a barrier stack, comprising:
forming one or more dyads, wherein forming each of the dyads comprises forming a first layer comprising a polymer or organic material, and forming an outer silicon nitride barrier layer; and
depositing an inner oxide barrier layer between the first layer and the outer silicon nitride barrier layer of one or more of the one or more dyads.

11. The method of claim 10, wherein the barrier stack including the inner oxide barrier layer has a water vapor transmission rate that is lower than a water vapor transmission rate of a barrier stack comprising the one or more dyads but not including the inner oxide barrier layer.

12. The method of claim 10, further comprising forming the first layer on a fourth layer.

13. The method of claim 10, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

14. The method of claim 10, wherein the outer silicon nitride barrier layer comprises Si₃N₄.

15. The method of claim 10, wherein the inner oxide barrier layer comprises an oxide of Al, Zr, Ti, Si, and combinations thereof.

16. The method of claim 10, wherein the inner oxide barrier layer comprises Al₂O₃ and/or SiO₂.

17. The method of claim 10, wherein the inner oxide barrier layer has a thickness of 20 nm or greater.

18. A barrier stack, comprising:
no more than 2 dyads, each dyad comprising a first layer comprising a polymer or organic material, and an outer silicon nitride barrier layer; and
an inner oxide barrier layer between the first layer and the outer silicon nitride layer of one or more of the no more than 2 dyads, wherein the barrier stack has a water vapor transmission rate on the order of 10^{31 4} g/m²·day or better.

19. The barrier stack of claim 18, wherein the no more than 2 dyads comprises no more than one dyad.

20. The barrier stack of claim 18, wherein the inner oxide barrier layer has a thickness of 20 nm or greater.
